(19) United States
(12) Patent Application Publication
(10) Pub. No.: US 2006/0081185 A1
(43) Pub. Date: Apr. 20, 2006

(54) Thermal management of dielectric components in a plasma discharge device

(76) Inventors: Justin Mauck, Fort Collins, CO (US); Steve Dillon, Fort Collins, CO (US); Juan Jose Gonzalez, Fort Collins, CO (US); Andrew Shabalin, Fort Collins, CO (US)

Correspondence Address: JOHN D. PIRNOT;ADVANCED ENERGY INDUSTRIES, INC., 1625 SHARP POINT DR., FORT COLLINS, CO, 80525, US

(21) Appl. No.: 10/966,904

(22) Filed: Oct. 15, 2004

(51) Int. Cl. C23C 16/00

(52) U.S. Cl. 118/723 I

(57) ABSTRACT

A plasma discharge device is provided having features for enhanced thermal management and protection of dielectric materials in the device. The invention generally comprises a plasma confinement chamber constructed at least in part of dielectric materials, with a cooling instrument disposed in contact with the outer dielectric surfaces of the chamber for substantially uniform heat extraction. The cooling instrument may be embedded within an encapsulating material that enhances the uniformity of heat extraction from a dielectric plasma chamber. By improving the uniformity of heat extraction from the dielectric chamber of a plasma discharge device, the invention permits reliable operation of a plasma discharge device at significantly improved power levels.

### BACKGROUND OF THE INVENTION

1. Field of the Invention

This invention relates generally to plasma discharge devices, and more particularly to thermal management and protection of dielectric materials in a plasma discharge device.

2. Brief Description of the Prior Art

A persistent challenge in the engineering of plasma discharge devices is control and removal of heat generated by the plasma. The ability of materials exposed to a plasma to withstand the thermal environment of the discharge often significantly restricts the performance, range, reliability, or other operating characteristics of a plasma device. Problems of thermal management are especially difficult in devices having dielectric materials in proximity to the plasma, particularly for structural purposes, owing to the poor thermal conductivity of most dielectrics. While certain dielectric materials such as ceramics may be tolerant of elevated temperatures in bulk, hot spots resulting from non-uniform cooling can lead to high internal stresses in dielectric components due to differential thermal expansions. It is not uncommon for these temperature-induced stresses to result in cracks in dielectric materials, leading in turn to premature failure of the plasma device.

A dielectric plasma containment vessel may be cooled using a conformal jacket or sheath that permits a cooling fluid to flow over the surface of the dielectric plasma vessel, as described for example in U.S. Pat. No. 5,200,595. For some applications, however, this approach presents an unacceptable risk that cooling fluid could enter the plasma chamber in the event of a break or crack and catastrophically contaminate processes occurring in or downstream of the chamber. A conformal cooling jacket may also impede the ability to provide inductive coupling of electromagnetic energy into the plasma unless the cooling jacket assembly itself and the cooling fluid therein are themselves dielectric.

One approach to cooling the dielectric chamber of an inductively coupled plasma device provides an arrangement of metal cooling tubes in proximity to the outer surface of the chamber, as for example a helical cooling coil disposed coaxially about a cylindrical chamber. Metal cooling tubes are commonly available and provide an efficient heat extraction path where placed in contact with the chamber body. Even where a plasma chamber has a relatively simple geometry, however, such as a cylinder, providing a metal cooling coil that is exactly conformal to the surface of the chamber is a manufacturing challenge. For example, a cooling coil that is prefabricated to have an inner major diameter larger that the outer diameter of the plasma chamber will be easy to assemble, but the gaps that necessarily exist between the coil and chamber wall will impair the uniformity and resistance of heat transfer from the chamber body to the cooling medium. On the other hand, a prefabricated coil having near-zero tolerance to the outer chamber wall will be difficult to mate to the chamber, and forced assembly of the article can still result in bunching or gapping of the coil along the length of the chamber as well as damage to the chamber wall. If the coil is not prefabricated but instead wound in place around the plasma tube, imperfect contact invariably results due to eccentricity of the winding and relaxation of the coil. Even small gaps resulting from these manufacturing imperfections lead to uneven cooling of the dielectric chamber, and consequently to hot spots in the chamber walls that limit the performance and reliability of the device. This process can also crack or damage the chamber during the manufacturing process.

In U.S. Pat. No. 6,156,667, a method of removing heat from a dielectric plasma chamber is described using a heat moderating material between the chamber and a cooling instrument. In this approach, the heat moderating material moderates the heat transfer between the dielectric and the cooling instrument to provide a temperature gradient through the dielectric material that minimizes failures such as breakage induced by thermal stress. The heat moderating material may also function as a heat spreader that maintains the surface of the dielectric at a cooler and more uniform temperature. A means is required of interposing the heat moderating material between the chamber and cooling instrument at a desired thickness during assembly of the article.

Others have addressed issues of temperature management in dielectric plasma chambers through the use of cooled or uncooled dielectric shields, or thin-walled metal cooling structures, located inside the dielectric confinement chamber. It would be desirable to improve the efficiency and uniformity of heat extraction from dielectric components of a plasma discharge device, and thereby to improve performance and reliability of the device, while retaining the benefits of a simple, sturdy, and cost-effective design.

### SUMMARY OF THE INVENTION

This invention provides a plasma discharge device having features for enhanced thermal management and protection of dielectric materials in the device. The invention generally comprises a plasma confinement chamber constructed at least in part of dielectric materials. A cooling instrument is disposed in contact with the outer dielectric surfaces of the chamber for substantially uniform heat extraction. Substantially direct and uniform contact between the dielectric surfaces and the cooling instrument is made possible by creating a temporary physical gap between the chamber and cooling instrument through mechanical, hydraulic, thermal or other means, then collapsing the gap so as to couple firmly heat extraction surfaces of the cooling instrument to outer surfaces of the chamber.

In one embodiment of the invention, a plasma source apparatus comprises a cylindrical plasma discharge tube that confines a plasma within. A helical coil constructed of square metal tubing is disposed coaxially about the outer surface of the dielectric discharge tube. The inward facing flat surfaces of the helical coil are in substantially direct and uniform contact with the outer surface of the dielectric discharge tube. A cooling fluid is flowed through the helical coil to extract heat transferred from the discharge tube to the metal coil. The turns of the cooling coil are spaced apart and electrically connected to an RF power source, thus allowing the cooling coil to function also as an inductive winding that couples RF power into the plasma within the discharge tube.

To assemble the cooling coil to the dielectric discharge tube, a temporary physical gap is created between the coil and the discharge tube. In one embodiment, the helical cooling coil is fabricated to have an inner major diameter that is slightly smaller than the outer diameter of the dielectric discharge tube. The cooling coil is placed into a fixture that allows it to be expanded by mechanical force until its inner major diameter is slightly larger than the outer diameter of the dielectric discharge tube. While the coil is expanded, the discharge tube is inserted into the space within the coil. The coil is then relaxed, causing the inward facing flat surfaces of the coil to come firmly into compressive contact with the outer surface of the discharge tube. In other embodiments of the invention, a helical cooling coil is twisted onto the body of a cylindrical dielectric plasma tube by applying torque in the direction of the turns of the helix. When the full length of the coil has been twisted onto the plasma tube the torque is released, causing the coil to fit firmly to the plasma tube surface. Alternatively, a temporary physical gap is created between the coil and the discharge tube by pressurizing the cooling coil, or by differentially heating the coil and/or cooling the dielectric tube.

In another aspect of the invention, the cooling instrument of a plasma discharge device is embedded within an encapsulation material that enhances the uniformity of heat extraction from a dielectric plasma chamber. The encapsulation material preferably has a low viscosity so as to displace residual air pockets between the dielectric chamber and the cooling instrument, along with a thermal conductivity that facilitates heat extraction from the chamber.

By improving the uniformity of heat extraction from the dielectric chamber of a plasma discharge device, the invention reduces hot spots within the chamber wall during operation that would limit the performance and reliability of the device. As a result, the features of the invention permit safe and reliable operation of a plasma discharge device at significantly improved power levels.

### BRIEF DESCRIPTION OF THE DRAWINGS

FIG. 1 illustrates a plasma source device in accordance with one embodiment of the invention.

FIG. 2 illustrates assembly of a cooling coil to the discharge tube of a plasma source device in accordance with one embodiment of the invention.

FIG. 3 illustrates use of an encapsulation material in accordance with another aspect of the invention.

### DETAILED DESCRIPTION

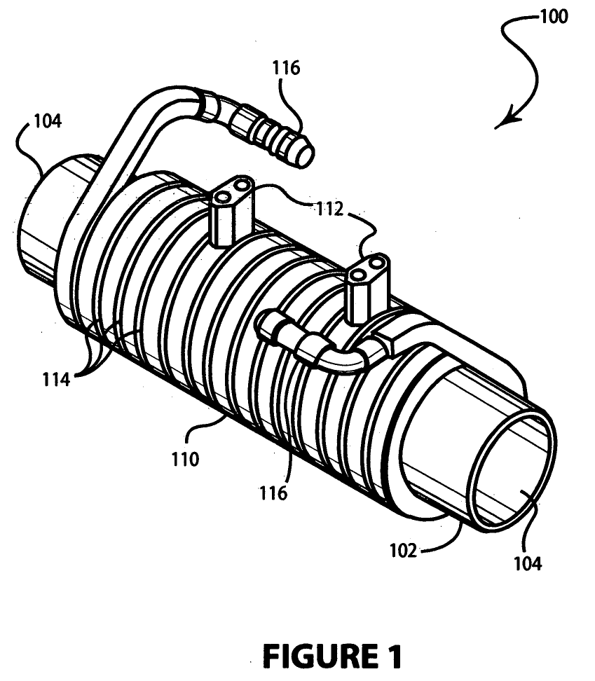

FIG. 1 illustrates a plasma source device in accordance with one embodiment of the invention. Plasma source 100 comprises cylindrical discharge tube 102 containing a plasma within. Discharge tube 102 is constructed substantially of a dielectric material such as quartz, alumina, aluminum nitride, or other structural dielectric suitable to the chemistry of the discharge environment within the tube. Discharge tube 102 is open at both ends 104 to allow for gas inlet and exhaust, as for example in an inline gas processing application. Alternatively, the plasma tube may be configured as a sealed vacuum chamber having metered inlet and exhaust ports for feed and processing gases. Not shown are other features that may typically be included in a plasma processing device such as vacuum pumping manifolds, gas delivery connections or manifolds, plasma ignition electrodes or other devices, and mechanisms for workpiece mounting, transfer, or electrical biasing.

Disposed coaxially about discharge tube 102 is helical metal cooling coil 110 constructed of square copper tubing. In the embodiment illustrated in FIG. 1, coil 110 functions both as a cooling instrument as well as an inductive winding that couples RF power into the plasma within discharge tube 102. An RF power generator (not shown) provides alternating current power to coil 110 through electrical taps 112 affixed to coil 110. When energized by an RF power source, plasma source 100 operates like an air core transformer with the coil 110 as the primary circuit and the plasma within discharge tube 102 as the secondary circuit. Insulating gaps 114 are maintained between the windings of coil 110, and taps 112 are located so as to provide a turns ratio desired on the primary circuit of the transformer-coupled source. Coil 110 is also provided with fittings 116 for connection of the coil to a source of coolant fluid (not shown).

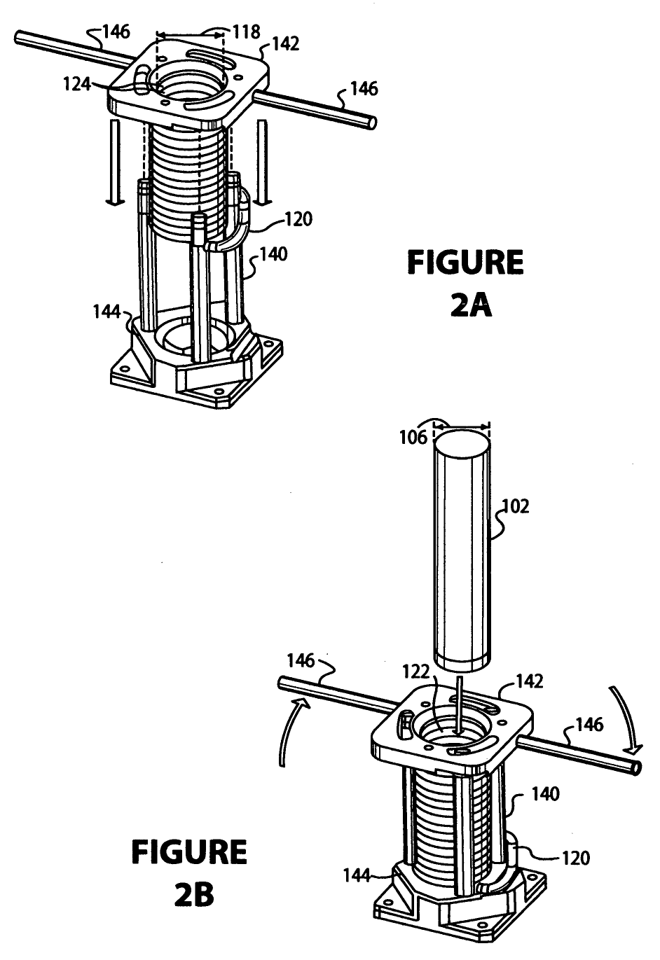

FIG. 2 illustrates assembly of coil 110 to discharge tube 102. Coil 110 is constructed having an inner major diameter 118 in its relaxed state that is smaller than the outer diameter 106 of cylindrical discharge tube 102. Coil 110 is placed into coil expansion fixture 140, where fitting ends 120 of coil engage and are temporarily fastened into mating grooves in upper and lower plates 142 and 144 of fixture 140. Torque is applied using fixture handles 146, radially expanding the coil until inner major diameter 118 of the coil is slightly larger than the outer diameter 106 of the discharge tube. While the coil is expanded, discharge tube 102 is inserted into expanded space 122 within the coil. Torque on handles 146 is released and the coil radially contracts, causing the inward facing flat surfaces of coil 110 to come firmly into compressive contact with the outer surface of discharge tube 102. In its assembled state, the coil thus exerts a residual compressive force upon the outer surface of discharge tube 102. In a preferred embodiment, the inner major diameter of coil 118 in its relaxed state is approximately 0.5-1.0% smaller than the outer diameter of dielectric discharge tube 102, which is held to a tolerance of ±0.001 inch. These dimensions are found to provide substantially direct contact between the dielectric discharge tube and cooling coil without undue compressive stresses on the tube.

Flat faces 124 of coil square tubing provide ample contact area between each turn of the coil winding and discharge tube 102. Alternatively, the coil is constructed of tubing having any cross sectional shape that provides substantially direct and uniform contact between the coil and discharge tube, while permitting coolant flow within the coil. Heat from discharge tube 102 is conducted through the contacting portions of cooling coil 110 and into a fluid coolant that flows therein. Preferably, coil 110 is fabricated of copper or other metal, but may be constructed of any resilient material that is both thermally and electrically conductive, and that is not vulnerable to cracking or fatigue due to thermal stresses.

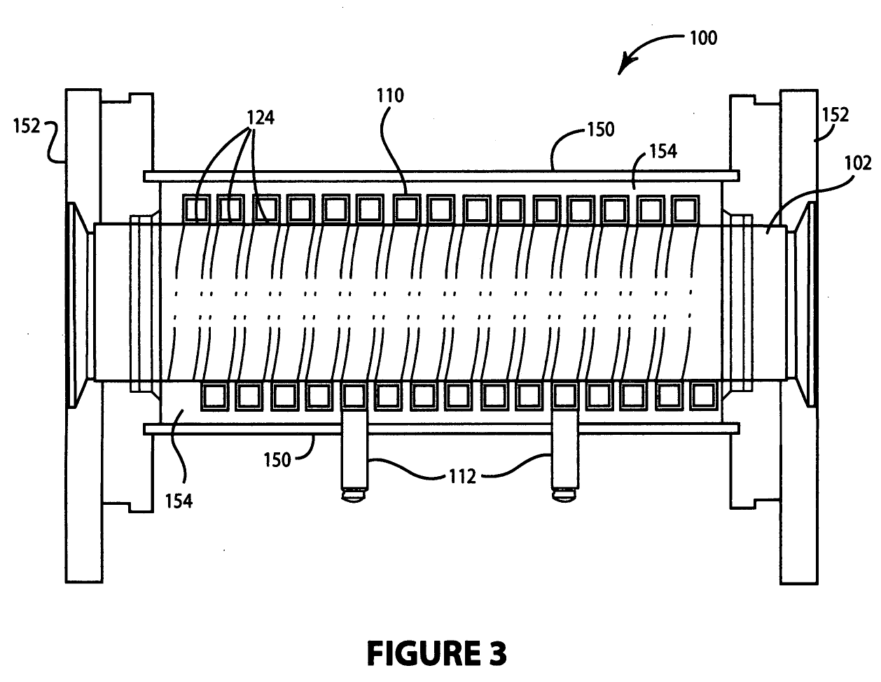

FIG. 3 illustrates the use of an encapsulation material in accordance with another aspect of the invention. In one embodiment, a cylindrical shell 150 is disposed coaxially about the discharge tube 102 with conformal cooling coils 110 of plasma source 100. Preferably, shell 150 is composed of polycarbonate or other polymeric material that is both flexible and visually transparent for ease of manufacture. Flanges 152 at each end of tube 102 seal the coaxial space between the shell 150 and tube 102. Through a window or other opening in the shell or flanges, an encapsulation material 154 is introduced into the coaxial space, embedding cooling coils 110. In its liquid phase, encapsulation material 154 has sufficiently low viscosity to displace virtually all air voids within the coaxial space, including between the turns of cooling coils 110 and any residual gaps that may exist between coils 110 and dielectric tube 102. Preferably, vacuum potting techniques are used to aid in removal of air pockets. Encapsulation material 154 is then cured into a rigid or solid state, at which time shell 150 may be left in place or removed.

In order to achieve the objectives of the invention, encapsulation material 154 has a unique combination of properties. The material must be dielectric to maintain electrical separation between windings of coil 110, should bond well to the dielectric surface of discharge tube 102, and should be flexible and exhibit minimal shrinkage in its cured state. Preferably, the material has high thermal conductivity to aid in thermal transfer from the discharge tube to the coils. Most importantly, the material must have sufficiently low viscosity in its liquid (pre-cured) state so as to displace trapped air in any small gaps between the cooling coil and discharge tube that would impede thermal transfer in these critical spaces. In a preferred embodiment of the invention, a two-part heat cured silicone adhesive is used as an encapsulation material.

In an alternative embodiment of the invention, a helical cooling coil is twisted onto the body of a cylindrical dielectric plasma tube by applying torque in the direction of the turns of the helix. When the full length of the coil has been twisted onto the plasma tube the torque is released, causing the coil to fit firmly to the plasma tube surface. Alternatively, a temporary assembly gap is created between a cooling coil and discharge tube by hydraulic or thermal means. In one embodiment, a fluid is injected into the coil under elevated hydrostatic pressure, which expands the coil radially. In another embodiment, the cooling tube is heated, causing it to expand, or the discharge tube is chilled, causing it to contract. In either case, following release of the mechanical, hydraulic or thermal assembly force(s), the parts return to their relaxed state and the coil mates firmly to the outer surface of discharge tube.

Although there is illustrated and described herein specific structure and details of operation, it is to be understood that these descriptions are exemplary and that alternative embodiments and equivalents may be readily made by those skilled in the art without departing from the spirit and the scope of this invention. Accordingly, the invention is intended to embrace all such alternatives and equivalents that fall within the spirit and scope of the appended claims.

What is claimed is:

1. A plasma discharge apparatus, comprising:
a) a discharge chamber for containing a plasma, the discharge chamber comprising a dielectric material exposed to heat generated by the plasma; and
b) an RF power source that couples RF power into the plasma through an inductive coil disposed about the discharge chamber, the inductive coil further disposed as a cooling instrument in contact with a surface of the dielectric material for substantially uniform heat extraction from the surface of the dielectric material.

2. The apparatus of claim 1 wherein the discharge chamber is comprised entirely of a dielectric material.

3. The apparatus of claim 1 wherein the discharge chamber is cylindrical.

4. The apparatus of claim 3 wherein the inductive coil is helical and mated coaxially to the outer surface of the cylindrical discharge chamber.

5. The apparatus of claim 1 wherein the inductive coil is disposed in substantially direct contact with the surface of the dielectric material.

6. The apparatus of claim 5 wherein the inductive coil exerts a residual compressive force on the discharge chamber.

7. The apparatus of claim 5 wherein the inductive coil is constructed of metal tubing.

8. The apparatus of claim 6 wherein the metal tubing has a flat surface in contact with the surface of the dielectric material.

9. The apparatus of claim 6 wherein the metal tubing contains a coolant fluid.

10. The apparatus of claim 1 wherein the inductive coil is embedded in an encapsulation material.

11. The apparatus of claim 10 wherein the encapsulation material is a silicone adhesive.

12. The apparatus of claim 10 wherein the discharge chamber is cylindrical and the encapsulation material fills a space between the cylindrical discharge chamber and a cylindrical shell disposed coaxially about the cylindrical discharge chamber.

13. The apparatus of claim 10 wherein the inductive coil is disposed in substantially direct contact with the surface of the dielectric material.

14. The apparatus of claim 13 wherein the encapsulation material fills residual gaps between the inductive coil and the surface of the dielectric material.

15. A method of operating a plasma discharge apparatus, comprising:
a) providing a plasma discharge apparatus comprising a discharge chamber for containing a plasma having at least one dielectric surface exposed to heat generated by the plasma, and an inductive coil disposed about the discharge chamber and in contact with the at least one dielectric surface;
b) coupling RF power through the inductive coil to the plasma; and
c) providing substantially uniform heat extraction from the at least one dielectric surface using the inductive coil.

16. The method of claim 15 wherein the discharge chamber is cylindrical.

17. The method of claim 16 wherein the inductive coil is helical and mated coaxially to the outer surface of the cylindrical discharge chamber.

18. The method of claim 15 wherein the inductive coil is disposed in substantially direct contact with the at least one dielectric surface.

19. The method of claim 15 wherein the inductive coil is embedded in an encapsulation material.

20. The method of claim 15, further comprising the step of flowing a coolant fluid through the inductive coil to extract heat from the inductive coil.

21. A method of constructing a plasma discharge apparatus, comprising:
a) providing a discharge chamber for containing a plasma comprised substantially of a dielectric material;
b) providing a helical inductive coil having an interior space bounded by inward facing surfaces of the inductive coil;
c) applying a force to create a temporary physical gap between the inward facing surfaces of the inductive coil and an outer surface of the discharge chamber;
d) inserting the discharge chamber into the interior space of the inductive coil; and
e) removing the force and thereby causing the inward facing surfaces of the inductive coil to come firmly into contact with the outer surface of the discharge chamber.

22. The method of claim 21 wherein the temporary physical gap is created by expanding the interior space of the inductive coil.

23. The method of claim 21 wherein the force is a mechanical, hydraulic, or thermal force.

24. The method of claim 21 wherein the discharge chamber is cylindrical.

25. The method of claim 21 wherein the inductive coil is constructed of metal tubing.

26. The method of claim 25 wherein the inward facing surfaces of the inductive coil metal comprise flat surfaces of the metal tubing.

27. The method of claim 21 wherein the metal tubing is disposed to contain a coolant fluid.

28. The method of claim 21, further comprising the step of embedding the inductive coil in an encapsulation material.

29. The method of claim 28, further comprising the step of vacuum potting the encapsulation material to remove air pockets.
